(19) United States
(12) Patent Application Publication
(10) Pub. No.: US 2026/0060072 A1
(43) Pub. Date: Feb. 26, 2026

(54) SEMICONDUCTOR DEVICE PACKAGE WITH SIDEWALL-COUPLED THERMAL ELEMENT AND METHOD OF MANUFACTURING THE SAME

(71) Applicants: ETRON TECHNOLOGY, INC., HSINCHU (TW); ND-HI TECHNOLOGIES LAB, INC., TAIPEI CITY (TW)

(72) Inventors: CHAO-CHUN LU, HSINCHU (TW); HO-MING TONG, TAIPEI CITY (TW)

(21) Appl. No.: 19/305,764

(22) Filed: Aug. 21, 2025

Related U.S. Application Data
(60) Provisional application No. 63/685,295, filed on Aug. 21, 2024.

(51) Int. Cl. H01L 23/34; H01L 25/04; H01L 25/16

(52) U.S. Cl. CPC H01L 23/34; H01L 25/04; H01L 25/16; H01L 2225/06562

(57) ABSTRACT

A semiconductor device package is provided. The semiconductor device package includes a stack structure comprising a plurality of electronic components vertically stacked relative to each other. Each of the plurality of electronic components is configured to provide electrical connectivity in a vertical direction. A first thermal element surrounds lateral surfaces of the stack structure and is thermally coupled to a lateral surface of at least one of the electronic components, thereby enhancing lateral heat dissipation efficiency of the stack structure.

### PRIORITY CLAIM AND CROSS-REFERENCE

This application claims the benefit of prior-filed U.S. provisional application No. 63/685,295, filed on Aug. 21, 2024 and incorporates by reference herein in its entirety.

### FIELD

The present invention relates to semiconductor device packages, and more particularly, to a semiconductor device package having a thermal element thermally coupled to sidewalls of a stack structure and a method of manufacturing the same.

### BACKGROUND

The exponential growth of data traffic necessitates the development of extremely advanced integrated circuits (ICs) and system-in-a-packages (SiPs), particularly for high-performance computing (HPC), data center, and artificial intelligence (AI) applications. Modern extreme processor ICs, built by advanced IC technology nodes beyond the 2 nm node, often require backside power delivery networks (BSPDN). Furthermore, extreme SiPs frequently incorporate 2.5D ICs, which include high-power extreme processor ICs (e.g., NVIDIA's H100 Graphics Processing Unit (GPU), which enabled ChatGPT and dissipates 700 W/GPU) and extreme high-bandwidth-memory (HBM) DRAM stacks (e.g., HBM3s, each containing 12 DRAM devices vertically mounted on a control IC and dissipating about 2 W). These components are typically mounted side-by-side on a large silicon interposer, with sizes currently around 53 mm×53 mm.

However, the power dissipation of GPUs is projected to increase significantly, from 700 W/chip to 2000 W/chip and beyond. Concurrently, as HBM scales from HBM3 to HBM4, the total number of dies in an HBM stack will grow from 13 to 17, with an expected increase in HBM power, while the HBM thickness is maintained at approximately 800 μm. High-end AI, HPC, and data center applications rely on massively parallel computation involving vast amounts of data, utilizing state-of-the-art GPUs and HBMs. Achieving higher performance often involves increasing the number of extreme GPUs and accompanying extreme HBMs mounted on even larger 2.5D interposers, with projected sizes growing from 53 mm×53 mm to 185 mm×185 mm and even beyond.

A significant challenge arises from the thermal sensitivity of memory devices, which are more susceptible to operating temperatures exceeding optimum ranges compared to logic devices like processors. With more dies vertically stacked in HBMs (e.g., from HBM3 to HBM4), it becomes highly desirable to utilize the peripheral sidewalls of the HBMs to dissipate heat during operation, in addition to the conventional HBMs'backside. This is particularly critical for bottom and middle-tier dies within the HBM, which are further away from the cold plate typically attached to the backside of HBMs and GPUs in a 2.5D IC. Moreover, the close proximity (within <1 mm) of higher-power GPU dies to HBMs in larger 2.5D ICs exacerbates the detrimental thermal effects on HBMs if heat dissipation is not properly managed.

While migration from the conventional front-side power delivery network to backside power delivery networks (BSPDN) and from FinFET to nanosheet transistors are crucial to scale future chips to below the 2 nm node, these solutions primarily address rapidly increasing power delivery and signaling complexities rather than the escalating thermal management challenges confronting future high-power 2.5D and 3D packages. Today, the most complex package for high-end AI and HPC applications is 2.5D IC which cools the high-power GPU and the HBMs from their backside through a combination of a heat spreader and a cold plate. To tackle the requirements of future 2.5D and 3D packages involving an exponentially increasing GPU power, there is a need to supplement this conventional, one-sided cooling (from the chip backside) by tapping into, particularly, the internal and sidewall regions of vertical 2.5D and 3D stacks to quickly spread the heat, to ensure both HBMs and also high-power processors operate at or around optimum operating temperatures.

### SUMMARY

According to some embodiments of the present disclosure, a semiconductor device package is provided. The semiconductor device package includes a stack structure comprising pluralities of electronic components vertically stacked relative to each other. Each of the pluralities of electronic components is configured to provide electrical connectivity in a vertical direction. A first thermal element is disposed to surround lateral surfaces of the stack structure and is thermally coupled to at least a lateral surface of at least one of the pluralities of electronic components.

According to some embodiments of the present disclosure, a semiconductor device package is provided. The semiconductor device package includes pluralities of electronic components stacked in a first direction and a first thermal element surrounding the pluralities of electronic components. The first thermal element is configured to conduct heat generated by at least a plurality of electronic components from at least one of its sidewalls both in a second direction toward the first thermal element and in the first direction toward a second thermal element. The first direction and the second direction are substantially orthogonal to each other.

According to some embodiments of the present disclosure, a method of manufacturing a semiconductor device package is provided. The method includes providing a carrier; arranging a stack structure comprising a plurality of electronic components stacked relative to one another on the carrier; and disposing a first thermal element on a lateral surface of the stack structure.

In order to further understanding of the instant disclosure, the following embodiments are provided along with illustrations to facilitate appreciation of the instant disclosure; however, the appended drawings are merely provided for reference and illustration, and do not limit the scope of the instant disclosure.

### BRIEF DESCRIPTION OF THE DRAWINGS

FIG. 1A is a schematic side view of a semiconductor device package according to some embodiments of the present disclosure.

FIG. 1B is a schematic cross-sectional view along line A-A′ in FIG. 1A.

FIG. 2A is a schematic cross-sectional view of a semiconductor device package according to some embodiments of the present disclosure.

FIG. 2B is a schematic cross-sectional view along line B-B′ in FIG. 2A.

FIG. 2C is a schematic cross-sectional view illustrating an exemplary high-thermal-conductivity (HTC) interposer disposed between a memory array die and a peripheral circuitry die in a stack structure of a semiconductor device package according to some embodiments of the present disclosure.

FIG. 2D is an enlarged view of portion “X” illustrated in FIG. 2C.

FIG. 3 is a partially enlarged cross-sectional view of a semiconductor device of a semiconductor device package according to some embodiments of the present disclosure.

FIG. 4 is a schematic cross-sectional view illustrating a portion of a semiconductor device of a semiconductor device package according to some embodiments of the present disclosure.

FIG. 5A is a schematic cross-sectional view of a semiconductor device package according to some embodiments of the present disclosure.

FIG. 5B is a schematic cross-sectional view along line C-C′ in FIG. 5A.

FIG. 6A, FIG. 6B, FIG. 6C, FIG. 6D and FIG. 6E illustrate one or more stages of an example of a method for manufacturing a semiconductor device package in accordance with some embodiments of the present disclosure.

FIG. 7A, FIG. 7B, FIG. 7C, FIG. 7D, FIG. 7E, FIG. 7F and FIG. 7G illustrate one or more stages of an example of a method for manufacturing a semiconductor device package in accordance with some embodiments of the present disclosure.

FIG. 8A, FIG. 8B, FIG. 8C, FIG. 8D, FIG. 8E, FIG. 8F and FIG. 8G illustrate one or more stages of an example of a method for manufacturing a semiconductor device package in accordance with some embodiments of the present disclosure.

### DETAILED DESCRIPTION

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, spatially relative terms, such as “beneath,” “below,” “above,” “over,” “on,” “upper,” “lower,” “left,” “right,” “vertical,” “horizontal,” “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

The present invention provides novel semiconductor device packages and associated manufacturing methods specifically engineered to enhance thermal management in high-density, vertically stacked electronic components. This is achieved, in various embodiments, by effectively utilizing a thermal element strategically coupled to the lateral surfaces of a stack structure comprising multiple electronic components. This sidewall thermal coupling provides an additional, highly effective pathway for heat dissipation, supplementing or in some cases replacing traditional one-sided, chip-backside cooling approaches. Consequently, the invention facilitates more efficient removal of heat generated within the stack, particularly from internal or heat-sensitive dies such as memory devices, and from high-power processors, thereby enabling lower operating temperatures and improved overall performance and reliability of the semiconductor device package.

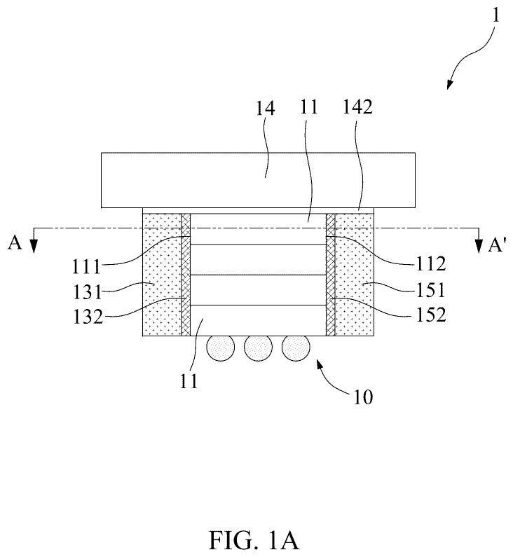

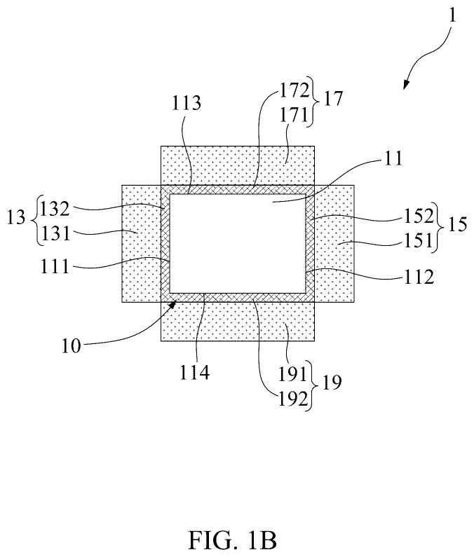

FIG. 1A is a schematic side view of a semiconductor device package 1 according to some embodiments of the present disclosure. As shown in FIG. 1A, the semiconductor device package 1 may include a stack structure 10. The stack structure 10 may include a plurality of memory devices 11 vertically stacked relative to each other. In some embodiments, the stack structure 10 may correspond to a high bandwidth memory (HBM) architecture, in which multiple memory dies are vertically integrated to form a compact and high-performance memory module.

Each of the memory devices 11 may comprise a memory die configured to perform data storage and access operations. The memory dies may be electrically connected to each other in the vertical direction via copper pillar micro-bumps and through-silicon vias (TSVs) that extend through the thickness of the individual dies. These TSVs allow for high-speed and low-latency communication between the vertically stacked memory dies and the processor with a logic die (such as a memory controller die) typically located at the base of the HBM stack.

The vertical stacking of the memory dies enables significant improvements in bandwidth and density compared to conventional planar memory packages. The stack structure 10 may also include one or more peripheral circuitry dies and/or logic dies that manage the operation of the memory devices 11.

As shown in FIG. 1A, a thermal element 131 may be attached to a lateral surface of the stack structure 10, and may thus be thermally coupled to the lateral surface of the stack structure 10. In this configuration, the thermal element 131 is thereby thermally coupled to a lateral surface 111 of at least one of the plurality of memory devices 11 within the stack structure 10. In some embodiments of the present disclosure, the thermal element 131 may comprise a high thermal conductivity (HTC) material. The HTC material may be in the form of a bulk material, a composite filler material comprising thermally conductive particles dispersed in a polymer matrix or a combination of a heat spreader and a thermal interface material (TIM).

Suitable high TC materials may include, but are not limited to, aluminum nitride (AlN), which has a thermal conductivity of approximately 170 to 321 W/m·K; silicon carbide (SiC), with a thermal conductivity of around 120 to 270 W/m·K; synthetic diamond, which can exhibit an extremely high thermal conductivity greater than 1500 W/m·K; and metallic materials such as copper (Cu), tungsten (W), molybdenum (Mo), or ruthenium (Ru), which have thermal conductivities in the range of approximately 100 to 400 W/m·K. In filler-based implementations, thermally conductive particles such as a metal (e.g., silver), AlN, boron nitride (BN), or graphite may be dispersed in a polymeric or epoxy resin to form a thermally conductive composite material that can conform to the lateral surface of the stack structure.

In some embodiments of the present disclosure, the thermal element 131 may be attached via a TIM 132 to improve thermal contact. The TIM 132 may include materials such as thermal grease, thermally conductive adhesive, or a phase change material, which reduces interfacial thermal resistance and promotes efficient lateral heat transfer from the memory dies of the stack to the external cooling path.

Further, a thermal element 151 may be attached to another lateral surface of the stack structure 10, and may thus be thermally coupled to the lateral surface of the stack structure 10. In this configuration, the thermal element 151 is thereby thermally coupled to a lateral surface 112 of at least one of the plurality of memory devices 11 within the stack structure 10. In some embodiments, the thermal element 151 may be substantially similar to, or identical in composition and function to, the thermal element 131. As such, the thermal element 151 may also comprise a high-thermal-conductivity (HTC) material, as previously described for the thermal element 131. In certain embodiments, the thermal element 151 may be bonded to the lateral surface of the stack structure 10 via a thermal interface material (TIM) 152, which facilitates improved thermal contact and heat transfer from the memory devices 11 to the thermal element 151.

In some embodiments of the present disclosure, additional thermal elements may be disposed on further lateral surfaces of the stack structure 10. As shown in FIG. 1B, which is a schematic cross-sectional view along line A-A′ in FIG. 1A, thermal elements 171 and 191 may be respectively attached to two remaining lateral surfaces of the stack structure 10 that are orthogonal to the lateral surfaces associated with thermal elements 131 and 151. Each of the thermal elements 171 and 191 may be thermally coupled to corresponding lateral surfaces of the stack structure 10 and may further be thermally coupled to lateral surfaces 113 and 114 of one or more of the memory devices 11 included in the stack structure 10.

In such embodiments, the thermal elements 131, 151, 171, and 191 which may be thermally coupled among themselves and which may collectively form a thermally conductive enclosure or wraparound structure that substantially surrounds the stack structure 10 from all four lateral sides. This configuration can significantly enhance the lateral heat dissipation capability of the semiconductor device package 1 by enabling multiple heat extraction paths away from the memory devices 11 and toward external heat spreaders, heat sinks, or cooling plates.

Each of the thermal elements 171 and 191 may be composed of the same or similar high thermal conductivity material as described with respect to the thermal elements 131 and 151. Additionally, each of the thermal elements 171 and 191 may be bonded to its corresponding lateral surface via a respective thermal interface material (TIM) 172 and 192. The TIMs 172 and 192 may improve the thermal coupling efficiency between the thermal elements and the stack structure 10 by reducing interfacial thermal resistance and ensuring reliable mechanical and thermal contact during thermal cycling.

Referring to FIG. 1A, a heat spreader 14 may be disposed over the stack structure 10. The heat spreader 14 may be thermally coupled to one or more of the thermal elements 131, 151, 171, and/or 191. In some embodiments of the present disclosure, the heat spreader 14 may be attached to the stack structure 10 and thermal elements 131, 151, 171, and/or 191 through a thermal interface material (TIM) 142. That is, heat generated by the memory devices 11 may be transferred from their respective lateral surfaces 111, 112, 113, and/or 114 through the corresponding thermal elements 131, 151, 171, and/or 191 to the heat spreader 14. In this manner, the heat spreader 14 functions as an external heat dissipation structure to collect and dissipate heat from multiple lateral paths of the stack structure 10.

In some embodiments, the heat spreader 14 may comprise a planar or conformal thermally conductive body that covers the top surface of the stack structure 10 and is in thermal contact with the upper ends of the thermal elements. The heat spreader 14 may be formed of a high thermal conductivity material such as copper (Cu), copper alloy, aluminum (Al), aluminum alloy, graphite-based composite, vapor chamber, or synthetic diamond. The heat spreader 14 may optionally be part of a larger cooling system, such as a cold plate or liquid-cooled module, to further enhance heat extraction from the stack structure 10.

In certain configurations, the heat spreader 14 may also include integrated micro-channels, heat pipes, or vapor chambers to facilitate single-phase, two-phase or convective heat transfer to ambient or external cooling hardware. The combined lateral and vertical thermal conduction paths described herein allow for more efficient and uniform heat dissipation, particularly in densely stacked semiconductor device packages such as high bandwidth memory (HBM) stacks and GPUs besides them.

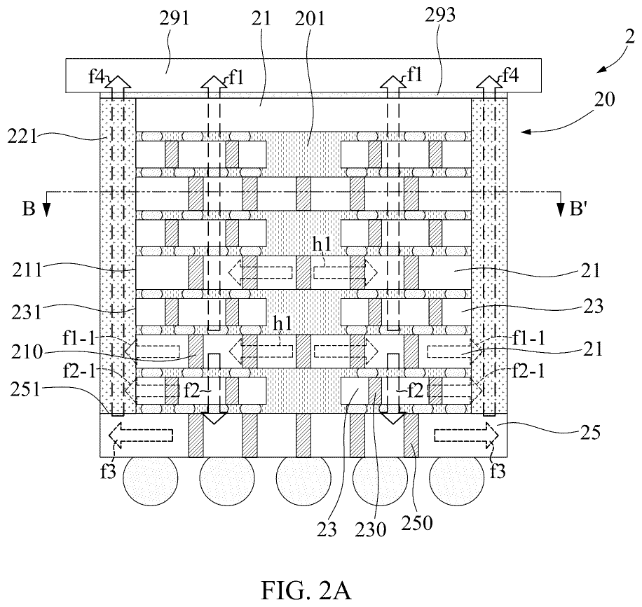

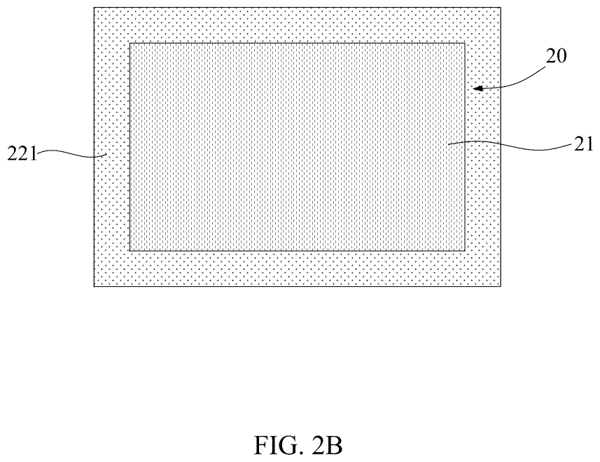

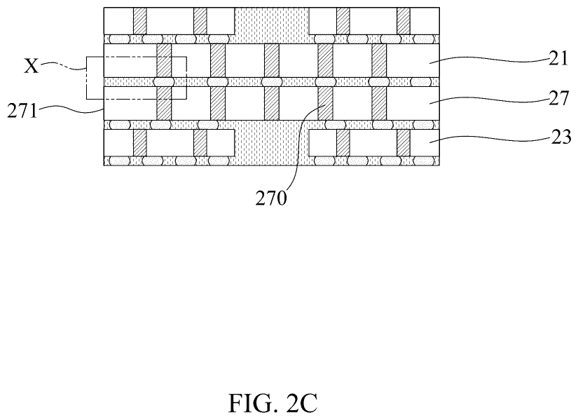

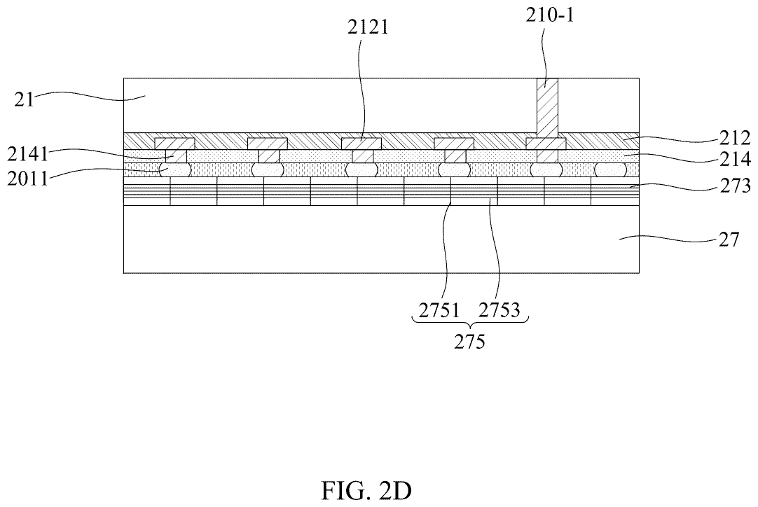

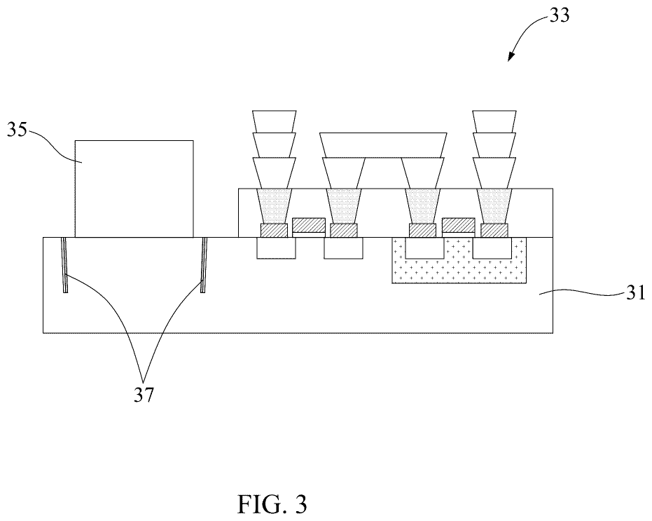

FIG. 2A is a schematic side view of a semiconductor device package 2 according to some embodiments of the present disclosure. As shown in FIG. 2A, the semiconductor device package 2 may include a stack structure 20. In some embodiments, the stack structure 20 may correspond to a high bandwidth memory (HBM) structure, which includes a plurality of vertically stacked memory array dies (memory portions of a DRAM, i.e., memory chiplets) 21 and peripheral circuitry dies (peripheral functions of the aforementioned DRAM, i.e., peripheral-die chiplets) 23, disposed over a logic die 25 (e.g., a control IC).

Referring to FIG. 2A, the logic die 25 may be positioned at the base of the stack structure 20 and may include memory control logic, I/O interfaces, or other functional circuitry for managing the operation of the memory dies. A first pair of peripheral circuitry dies 23 may be disposed over an upper surface 251 of the logic die 25. A first memory array die 21 may then be stacked over the two peripheral circuitry dies 23. The peripheral circuitry die functions can include row decoder, column decoder, sense amplifier, timing control circuitry, address multiplexer, data input/output buffer, refresh logic, power management and control logic. Subsequently, a second pair of peripheral circuitry dies 23 may be stacked over the first memory array die 21, and a second memory array die 21 may be stacked at the top of the structure, over the second pair of peripheral circuitry dies 23. In this manner, the memory array dies 21 and peripheral circuitry dies 23 are alternately stacked on top of the logic die 25 to form the vertically integrated stack structure 20, wherein the topmost electronic component may be the memory array die 21.

Each of the memory array dies 21 may include a plurality of through-silicon vias (TSVs) 210 configured to electrically connect the memory dies in the vertical direction in conjunction of copper pillar micro-bumps. Similarly, each of the peripheral circuitry dies 23 may include TSVs 230, and the logic die 25 may include TSVs 250. The TSVs, 210, 230, and 250, and the copper pillar micro-bumps may together form a vertical signal and power delivery path through the entire stack structure 20, thereby allowing for high-speed communication and efficient power distribution among the various tiers of dies.

In some embodiments, the TSVs, 210, 230, and 250 may include or be accompanied by thermal conductive vias configured to provide vertical thermal conduction through the stack structure 20. These thermal conductive vias may be implemented as dedicated heat-conducting structures. For example, they may be formed of thermally conductive materials such as copper (Cu), tungsten (W), or molybdenum (Mo), and may be strategically located near high-power regions of the memory array dies 21, the peripheral circuitry dies 23, or the logic die 25. The thermal conductive vias allow heat generated in the mid-tier dies of the stack structure 20 to be effectively transferred both upward to the cold plate, downward through lower-tier dies to the logic die 25 and laterally through a sidewall to a thermal element 221 and then to a heat spreader 291 (attached to a water-circulated cold plate, not shown) which is thermally coupled to the thermal element 221.

In some embodiments, the stack structure 20 may be fabricated using wafer-to-wafer or die-to-wafer bonding techniques using micro-bumps or copper hybrid bonding. The use of TSVs enables the reduction of interconnect length and parasitic resistance, thereby increasing the overall bandwidth and lowering latency, which are key performance advantages of HBM architectures.

Furthermore, the stacked configuration of memory array dies and peripheral circuitry dies allows for the physical separation of dense memory cell arrays from high-activity peripheral circuits such as row/column decoders and sense amplifiers, which may contribute to more efficient thermal management and layout optimization. The vertical interleaving of memory and peripheral dies also allows for scalability in memory density and bandwidth by increasing the number of tiers.

Further, the semiconductor device package 2 may include an encapsulant 201 within the stack structure 20. The encapsulant 201 may be used to fill the spaces created between the logic die 25, the memory array dies 21, and the peripheral circuitry dies 23 using flip chip assembly based on micro-bumps. In some embodiments, the encapsulant 201 may comprise an underfill material, a molding compound, a flowable epoxy resin, or a non-conductive film or paste, depending on the packaging process used.

The encapsulant 201 may serve multiple purposes, including providing mechanical support to the stacked structure, protecting the semiconductor dies from environmental contaminants (such as moisture or dust), and mitigating thermal and mechanical stress during temperature cycling. In wafer-level or panel-level packaging processes, the encapsulant 201 may be applied during flip chip assembly or using compression molding, transfer molding, or vacuum-assisted injection to ensure void-free filling between adjacent dies. In some configurations, the encapsulant 201 may be made of a HTC material and exhibits thermally conductive properties to assist in lateral heat spreading from the interior of the stack structure toward adjacent thermal elements.

As shown in FIG. 2A, a thermal element 221 may be attached to lateral surfaces of the stack structure 20, and may thereby be thermally coupled to the lateral surfaces of the stack structure 20. In this configuration, the thermal element 221 may be thermally coupled to at least a lateral surface 211 of one or more memory array dies 21 and/or a lateral surface 231 of one or more peripheral circuitry dies 23 included in the stack structure 20. In some embodiments, the thermal element 221 may additionally extend onto or be disposed on the upper surface 251 of the logic die 25, and thereby be thermally coupled to the logic die 25 as well.

In certain embodiments, the thermal element 221 may comprise a HTC material. The HTC material may be provided in the form of a solid bulk structure, a combination of a heat spreader and a TIM, or a composite filler comprising thermally conductive particles dispersed in a polymeric matrix. In some implementations, the thermal element 221 may be formed by filling a cavity created between the lateral surfaces of the stacked dies and an outer encapsulant or mold wall with a HTC filler. The HTC filler may then be cured or solidified to form a conformal thermal structure in direct or indirect contact with the stacked dies. Such filler-based thermal elements are particularly suitable for panel-level or wafer-level packaging processes and allow for effective thermal contact with complex lateral geometries of multi-die stacks.

Suitable high TC materials may include, but are not limited to, aluminum nitride (AlN), which has a thermal conductivity of approximately 170 to 321 W/m·K; silicon carbide (SiC), with a thermal conductivity of approximately 120 to 270 W/m·K; synthetic diamond, which can exhibit an extremely high thermal conductivity greater than 1500 W/m·K; and metallic materials such as copper (Cu), tungsten (W), molybdenum (Mo), or ruthenium (Ru), with thermal conductivities typically ranging from about 100 to 400 W/m·K. In filler-based embodiments, thermally conductive particles such as a metal (e.g., silver), AlN, boron nitride (BN), or graphite may be dispersed within a polymer resin or epoxy to form a composite thermal material that can conform to the shape of the die stack and make direct thermal contact with the lateral surfaces of individual dies.

Moreover, as shown in FIG. 2B—which is a schematic cross-sectional view along line B-B′ in FIG. 2A—the thermal element 221 may at least partially or fully surround the stack structure 20, and may thus be thermally coupled to all of the lateral surfaces of the stack structure 20. In this configuration, the thermal element 221 may form a continuous or segmented thermally conductive element or enclosure around the sides of the stack structure. Such a wraparound thermal design enables uniform lateral heat extraction from all sides of the stack, which is particularly advantageous in high-density memory stacks such as HBM, where thermal buildup in intermediate tiers can be problematic. In some embodiments, the thermal element 221 may also serve to guide heat toward an external heat spreader (e.g., heat spreader 291 in FIG. 2A) or toward a top-mounted or bottom-mounted heat sink through direct contact or via intermediate thermal interface layers.

Referring to FIG. 2A, a heat spreader 291 may be disposed over the stack structure 20. The heat spreader 291 may be thermally coupled to the thermal element 221 to facilitate the dissipation of heat conducted from the lateral surfaces of the stack. In some embodiments, the heat spreader 291 may be attached to both the topmost memory array die 21of the stack structure 20 and the upper portions of the thermal element 221 via a thermal interface material (TIM) 293. The TIM 293 may improve thermal contact and reduce interfacial resistance between the heat spreader and the underlying components.

In some embodiments, the heat spreader 291 may comprise a planar or conformal thermally conductive body configured to cover the top surface of the stack structure 20 (i.e., die backside). It may be in direct thermal contact with the upper ends of the thermal element 221 and with the exposed surface of the topmost memory array die 21 and backside of a high-power processor placed side-by-side with the stack structure 20. The heat spreader 291 may be formed from high thermal conductivity materials such as copper (Cu), copper alloy, aluminum (Al), aluminum alloy, graphite-based composite, vapor chamber, or synthetic diamond. In certain implementations, the heat spreader 291 may also be part of a larger heat dissipation system, such as a cold plate, a liquid immersion cooling module, a vapor chamber-based thermal assembly, a thermos-electric cooler, or a combination thereof, configured to enhance heat removal from the entire package.

In some configurations, the heat spreader 291 may include integrated thermal structures such as micro-channels, heat pipes, or vapor chambers, which promote two-phase heat transfer or forced/convection-based cooling thermally coupled to ambient or external thermal management systems. The combination of lateral thermal conduction through the thermal element 221 and vertical thermal conduction through the heat spreader 291 enables efficient and uniform heat dissipation throughout the stack structure 20. This is particularly beneficial in densely stacked memory architectures such as high bandwidth memory (HBM), where thermal accumulation within intermediate dies can degrade performance and reliability.

The heat conduction paths within the semiconductor device package 2 will now be described by way of example. As shown in FIG. 2A, the memory array dies 21 may generate heat, denoted as h1, during operation. A portion of the generated heat h1 may be conducted vertically upward through the through-silicon vias (TSVs) 210 and 230 and subsequently transferred to the heat spreader 291 located at the top of the stack structure 20. This vertical conduction path is referred to as flow f1. Furthermore, a portion of the generated heat h1 may be laterally conducted through the lateral surfaces of the memory array die 21 and subsequently transferred to the thermal element 221, as indicated by heat flow path f1-1.

Another portion of the heat h1 may be conducted downward through the TSVs 210 and 230 to reach the underlying logic die 25, as indicated by flow f2. Once the heat reaches the logic die 25, it may be laterally transferred into the thermal element 221, which is thermally coupled to the logic die 25, represented as flow f3. In addition, another portion of the heat h1 may be laterally conducted through the lateral surfaces of the peripheral die 23 and subsequently transferred to the thermal element 221, as indicated by heat flow path f2-1. The thermal element 221 may then conduct the heat upward along the lateral surfaces of the stack structure 20, ultimately delivering the heat to the heat spreader 291 from the sides, as shown by flow f4.

Through this configuration, the package achieves a combined vertical and lateral thermal dissipation architecture, where the thermal element 221 provides an additional heat conduction path that supplements TSV-based vertical conduction. The thermal element 221 expands the available heat transfer surfaces and enables the redirection of heat from intermediate tiers of the stack toward the heat spreader. This not only reduces thermal concentration within the central portions of the stack but also contributes to a more uniform temperature profile throughout the package. Similar comments can be made on high-power processors regarding heat dissipation through their sidewalls with the assistance of the thermal element 221. As a result, the presence of the thermal element 221 improves the overall thermal efficiency of the semiconductor device package and enhances operational reliability under high-performance conditions, particularly in high-density memory stack configurations such as HBM architectures.

In some embodiments of the present disclosure, the stacking of the memory array die 21 and the peripheral circuitry die 23 within the stack structure 20 may include a HTC interposer 27 inserted between them to help absorb and dissipate the heat generated. As shown in FIG. 2C, the HTC interposer 27 may be disposed between the memory array die 21 and the peripheral circuitry die 23 such that the memory array die 21 is positioned over and thermally coupled to the upper surface of the HTC interposer 27, and the peripheral circuitry die 23 is disposed beneath and thermally coupled to the lower surface of the HTC interposer 27.

The HTC interposer 27 may include through-silicon vias (TSVs) 270 that provide both electrical connectivity and vertical thermal conduction. In some embodiments, the TSVs 270 may incorporate thermally conductive vias composed of HTC materials such as copper (Cu), tungsten (W), or other thermally efficient metals, thereby facilitating heat transfer across the vertical direction of the stack. The HTC interposer 27 may be formed of a material having a thermal conductivity greater than that of silicon (approximately 150 W/m·K). In contrast, the HTC interposer 27 may comprise materials such as aluminum nitride (AlN), with a thermal conductivity of approximately 321 W/m·K, or synthetic diamond, with an extremely high thermal conductivity of approximately 1500 W/m·K or higher. For the purposes of the present disclosure, an “HTC interposer” is defined as an interposer composed of a material having a thermal conductivity greater than that of silicon (with a thermal conductivity of around 148 W/m·K). This definition allows the HTC interposer 27 to be clearly distinguished from silicon-, molding-compound-or glass-based interposers.

Furthermore, in some embodiments, the lateral surface 271 of the HTC interposer 27 in FIG. 2C may be attached to or thermally coupled to the aforementioned thermal element 221. In this configuration, heat generated by the memory array die 21 may be transferred both directly to the thermal element 221 and downward into the HTC interposer 27 and then conducted laterally through the interposer toward the thermal element 221. The combination of vertical heat flow into the HTC interposer and lateral heat spreading to the thermal element 221 enables the HTC interposer 27 to function as an intermediate thermal bridge. This enhances overall heat dissipation efficiency within the stack structure 20, particularly by offloading thermal stress from the memory array die 21 and promoting efficient transfer of heat to the thermal element 221, which then conducts the heat toward an external cooling structure such as a heat spreader, a cold plate, a thermos-electric cooler, a liquid immersion apparatus or a combination thereof.

FIG. 2D is an enlarged view of portion “X” illustrated in FIG. 2C. The memory array die 21 may comprise a front-end-of-line (FEOL) layer 212 and a back-end-of-line (BEOL) layer 214. The FEOL layer 212 typically includes active devices such as transistors, as well as isolation structures such as shallow trench isolation (STI) structures that separate these devices. In contrast, the BEOL layer 214 includes the multilayered interconnect structures, such as metal lines and vias, used to route electrical signals and power between active devices in the FEOL layer 212.

In some embodiments of the present disclosure, the FEOL layer 212 may include a plurality of thermal STI structures 2121. STI structures 2121 may be conventionally used to provide electrical isolation between adjacent transistors. However, they may also provide lateral and/or vertical lateral thermal conduction paths through the implementation of thermally conductive routings (e.g., W routings) created within the STIs 2121 which may be thermally coupled to a thermal via 2141 in the BEOL layer 214, a thermal conductive via 210-1 in the FEOL layer and in the silicon substrate, a thermal bump 2011, a thermal dissipation structure 275 in the HTC interposer 27 and the thermal element 221.

In some embodiments, the memory array die 21 may further include a thermal conductive via 210-1 extending vertically through at least a portion of the memory array die 21. The thermal conductive via 210-1 may be configured to transfer heat from an electronic component disposed above the memory array die 21—for example, another memory array die 21 in a vertically stacked HBM structure. In some embodiments, the thermal conductive via 210-1 may extend into the FEOL layer 212 and be thermally coupled to one or more of the STI structures 2121, thereby facilitating more efficient heat flow into the lower, upper and lateral structural layers of the die.

The BEOL layer 214 of the memory array die 21 may include a plurality of thermal vias 2141. These thermal vias 2141 may be formed of thermally conductive materials such as copper or tungsten and may vertically connect different metal layers within the BEOL to provide a low-resistance path for heat conduction. In some embodiments, the thermal vias 2141 may be thermally coupled to the STI structures 2121 in the FEOL layer, forming an integrated vertical thermal network that bridges the FEOL and BEOL layers.

Moreover, a plurality of thermal bumps 2011 may be disposed between the memory array die 21 and the HTC interposer 27. These thermal bumps 2011 may be formed of solder, micro-bump or metal composite materials with a HTC and may be thermally coupled to the thermal vias 2141 of the BEOL layer 214 to facilitate direct heat transfer from the memory die to the interposer.

Further, redistribution layers (RDL) 273 may be disposed on the HTC interposer 27 and be thermally coupled to the thermal bumps 2011. RDLs are typically used to reroute electrical connections on a chip or package to allow for different bonding configurations or fan out requirements. In some embodiments of the present disclosure, the redistribution layer 273 may be additionally configured to enhance thermal dissipation and may include a heat dissipation structure 275. The heat dissipation structure 275 may comprise a plurality of thermal vias 2751 configured to transfer heat predominantly in the vertical direction, and a plurality of thermal planes 2753 configured to transfer heat predominantly in the lateral direction. In some embodiments of the present disclosure, the lateral side of the heat dissipation structure 275 may be thermally coupled to the thermal element 221. More specifically, the thermal planes 2753 of the heat dissipation structure 275 are configured to laterally transfer heat to the thermal element 221, significantly increasing the heat conduction efficiency by providing an effective lateral pathway to the external cooling element.

FIG. 3 is a partially enlarged cross-sectional view of a semiconductor device, which may correspond to one of the memory devices 11 shown in FIG. 1A, the memory array dies 21, the peripheral circuitry dies 23, or the logic die 25 shown in FIG. 2A.

Referring to FIG. 3, the semiconductor device includes a silicon substrate (p-type Si) 31, over which multiple circuit regions are formed. Following front-end-of-line (FEOL) processing, a plurality of transistor structures are fabricated on the silicon substrate 31. These transistor structures may include n+ type and p+ type source/drain regions, as well as gate electrodes (G). Among these, a subset may form a high-power circuit region 33, which tends to generate significant heat during operation. The device may also include a low-power circuit region 35, such as a temperature-sensitive circuit.

Above the FEOL transistor structures, BEOL layers are formed using standard semiconductor manufacturing techniques. These BEOL layers typically include multiple levels of metal interconnects, such as copper (Cu) or tungsten (W), along with dielectric materials for electrical insulation. A barrier layer is also often implemented in conjunction with metal interconnects to prevent metal diffusion and ensure structural integrity.

A key feature of this embodiment is the integration of a thermal management structure 37. The thermal management structure 37 may be composed of silica (SiO₂) and graphene-based materials, or copper and polydimethylsiloxane (PDMS), or polystyrene, Inconel 625 alloy, and aluminum, or copper and stainless steel, etc. and may be strategically positioned within the semiconductor device to optimize thermal performance. Such a structure may represent a thermal metamaterial structure, exhibiting thermal properties that do not exist in nature but can be rationally designed to offer unique capabilities of controlling heat transfer within the semiconductor device. As illustrated in FIG. 3, the thermal management structure 37 may surround or partially surround the low-power circuit region 35 to thermally isolate it from the adjacent high-power circuit region 33.

In various embodiments, the thermal management structure 37 may be implemented using different classes of thermal metamaterials depending on the desired thermal regulation function. For example, in implementations requiring anisotropic heat spreading, the thermal management structure 37 may incorporate two disparate materials such as copper and polydimethylsiloxane (PDMS) to achieve directionally enhanced thermal conductivity, enabling efficient lateral heat transport and uniform temperature distribution to avoid hot spots.

In other embodiments, the thermal management structure 37 may serve as a thermal cloaking and isolating layer, utilizing materials such as copper/PDMS composites or a layered configuration comprising polystyrene (as the inner layer), Inconel 625 (as the outer layer), and aluminum (as the cloaked object). These configurations enable transient thermal protection, in which the temperature within the cloaked region remains lower than its surroundings, thereby effectively shielding temperature-sensitive circuitry such as the low-power circuit region 35 from adjacent high-heat-generating zones.

Additionally, the thermal management structure 37 may implement heat guiding and bending functions by using composite materials such as copper and stainless steel. This type of metamaterial is capable of steering heat flow along predetermined pathways within the semiconductor device, offering both thermal routing flexibility and good manufacturability.

Functionally, the thermal management structure 37 acts as a thermal metamaterial engineered to inhibit or redirect heat flow. It primarily serves as a thermal barrier to prevent heat generated in the high-power region 33 from reaching the low-power circuit region 35, which is a heat-sensitive circuit region. Additionally, the structure may be configured to redirect the intercepted heat toward predetermined thermal dissipation paths or thermally robust areas within the device.

By implementing such a thermal management structure, thermal cross-talk between densely packed high-power and thermally sensitive regions can be effectively minimized. This allows the temperature-sensitive circuits to operate in a more thermally stable environment, thereby enhancing device reliability, thermal performance, and overall longevity.

Moreover, the thermal management structure 37 may be further configured to channel heat laterally toward external thermal dissipation elements, such as the thermal elements 131, 151, 171, 191, or 221, thereby facilitating efficient integration with the broader heat management architecture of the semiconductor package.

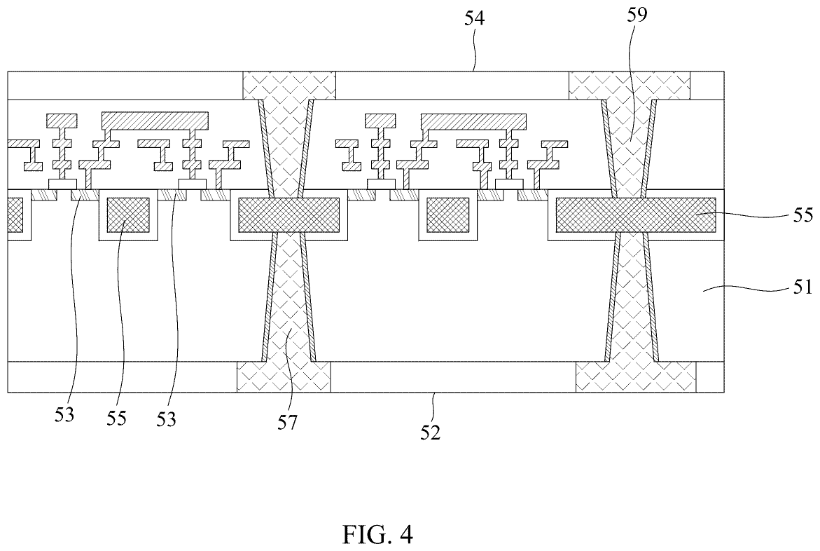

Referring to FIG. 4, an embodiment of the present disclosure is illustrated, which shows a schematic cross-sectional view of a semiconductor device. The semiconductor device may correspond to one of the memory devices 11 shown in FIG. 1A, or one of the memory array dies 21, peripheral circuitry dies 23, or the logic die 25 shown in FIG. 2A.

The semiconductor device may include a silicon substrate 51, on which a plurality of transistors 53 are formed. During device operation, these transistors 53 may serve as primary heat sources, generating significant localized thermal energy.

The device may further include multiple shallow trench isolation (STI) structures 55. As shown in FIG. 4, the STI structures 55 may be disposed between adjacent transistors 53 and extend into the interior of the silicon substrate 51. Conventionally, STI structures are employed for electrical isolation, preventing leakage currents or crosstalk between adjacent devices. However, in the present embodiment, the STI structures 55 are innovatively adapted to function not only as electrical insulators but also as thermally conductive pathways.

Specifically, each STI structure 55 may be formed of, or filled with, materials that exhibit higher thermal conductivity than the surrounding silicon substrate and adjacent dielectric layers. Alternatively, the geometry of the STI structures 55 may be optimized to facilitate directional heat flow. For instance, the STI structures may incorporate composite thermally conductive materials or be patterned in such a way that they serve as effective thermal channels for removing heat from localized hot spots.

When thermal energy is generated by the transistors 53, it may be intercepted and conducted by the STI structures 55 in close proximity along predefined directions. This thermal guidance function allows the STI structures to efficiently transport heat away from the transistor regions. In some configurations, heat may be routed toward surrounding thermal vias 57 and/or 59 or the aforementioned thermal paths integrated within the stack structure 20.

Moreover, the STI structures 55 may work in conjunction with other thermal management components. As illustrated in FIG. 4, a thermal via 57 may be thermally coupled to the lower portion of an STI structure 55 to facilitate vertical heat conduction toward the backside 52 of the semiconductor device, where a thermally enhanced RDL layer or other thermal dissipation component may reside. Incidentally, the thermal via 57 can be integrated with the BSPDN. Similarly, heat may also be transferred through another thermal via 59 in the BEOL layer and/or laterally through extended thermally conductive planes residing on the front side RDL layer or BEOL layer 54 of the semiconductor device.

Additionally, lateral heat transport may be provided by thermally coupling the STI structures 55 to one or more lateral thermal elements, such as thermal elements 131, 151, 171, 191, or 221, located at the sidewalls of the device. These thermal elements serve as part of the broader thermal dissipation architecture and help further enhance heat extraction efficiency from localized hotspots within the semiconductor device.

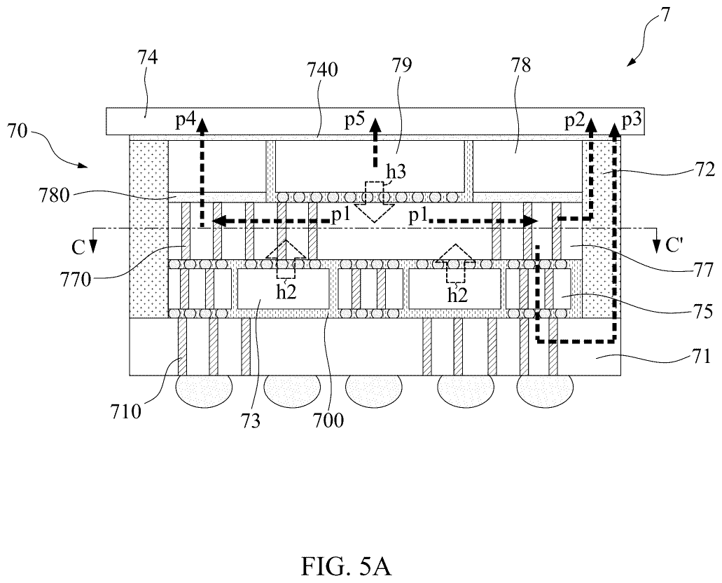

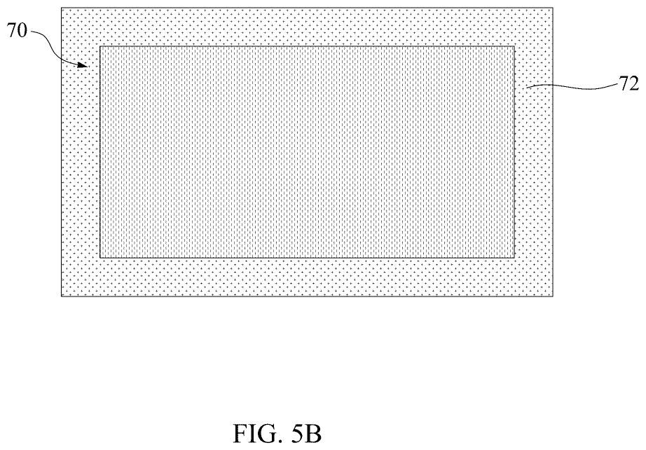

FIG. 5A is a schematic side view of a semiconductor device package 7 according to some embodiments of the present disclosure. As shown in FIG. 5A, the semiconductor device package 7 may include a stack structure 70.

The stack structure 70 may comprise an interposer 71, a plurality of memory components 73 which can be HBMs, a plurality of bridge components 75, a high-thermal-conductivity (HTC) interposer 77, one or more heat spreader plates 78, and a semiconductor device 79 which can be a high-power processor.

The interposer 71 may include a plurality of TSVs 710. The interposer 71 may include a large silicon interposer (or a large HTC interposer such as a diamond interposer), providing a large enough substrate for mounting various components in a 2.5D or 3D package. The TSVs 710 in the interposer 71 are primarily utilized for electrical connectivity between components mounted on the interposer and the underlying substrate. Furthermore, some of these TSVs 710 may also include thermally conductive vias, designed to facilitate vertical heat transfer through the interposer 71, thereby contributing to the overall thermal management of the package.

The bridge components 75 may be disposed on the interposer 71 and electrically and thermally coupled thereto through micro-bump connections. Each bridge component 75 which can be a passive or an active component provides high-density routing layers, and functions as an intermediary between high-speed chips such as logic dies and memory dies. The bridge component can be one of the following: (a) stacked silicon, glass or HTC-material interposer-lets (with through vias and redistribution layers) that resembles HBM stacking; (b) stacked fanout layers with through vias and/or vertical wires; (c) stacked package-on-package (PoP) layers with through vias and/or vertical wires; (d) co-packaged HBM and stacked bridges (using, for instance, fan-out), or (e) a combination of (a) to (d). These bridge components facilitate both power delivery (e.g., to a GPU) and signaling. In high-performance packages, such as those involving GPU-HBM architectures, the bridge components 75 are essential to support high bandwidth and low latency communication.

The high-thermal-conductivity (HTC) interposer 77 may be disposed above the bridge components 75 and be electrically and thermally coupled thereto via micro-bump connections. The HTC interposer 77 may include a plurality of TSVs 770 that provide both vertical electrical and thermal conduction. The HTC interposer 77 may be formed from a material with a thermal conductivity greater than around 148 W/m·K (thermal conductivity of silicon)—substantially higher than that of glass or molding compound (˜1 W/m·K). Suitable materials for the HTC interposer 77 may include, but are not limited to, aluminum nitride (AlN), which has a thermal conductivity of approximately 321 W/m·K, and synthetic diamond, which may exhibit thermal conductivity in excess of 1500 W/m·K and up to 2400 W/m·K. The use of such materials allows the HTC interposer 77 to serve not only as a high-performance electrical interconnect layer but also as an efficient thermal conduit for dissipating heat generated by high-power devices atop the HTC interposer 77.

The memory components 73 may be disposed between the interposer 71 and the HTC interposer 77, and may be mounted to a lower surface of the HTC interposer 77. In some embodiments, the memory components 73 may be electrically and thermally coupled to the HTC interposer 77 through micro-bump connections. Each memory component 73 may include one or more memory dies, such as DRAM dies or can represent the DRAM chiplet structure shown in FIG. 2A. Similar chiplet structures can be envisaged for processors or processors and memory devices combined. In high-bandwidth applications, the memory components 73 may be implemented as High-Bandwidth Memory (HBM) stacks comprising multiple vertically stacked DRAM dies interconnected with TSVs. These HBM stacks provide a compact, high-density memory solution with large data throughput and integrated thermal dissipation structures.

The semiconductor device 79 may be disposed atop the HTC interposer 77 and be electrically and thermally coupled thereto via micro-bump connections. The semiconductor device 79 may be a high-power logic chip, such as GPU, Central Processing Unit (CPU), Field-Programmable Gate Array (FPGA), Application-Specific Integrated Circuit (ASIC) or Neural Processing Unit (NPU). In some embodiments, the GPU may be a high-performance unit such as NVIDIA's GB200, which can dissipate up to 1,200 W/GPU chip, with future designs potentially exceeding 2000 W/chip.

One or more heat spreader plates (or structural silicon) 78 may be disposed above the HTC interposer 77, surrounding portions or the entirety of the semiconductor device 79. These heat spreader plates 78 may be thermally coupled to the HTC interposer 77 via a HTC adhesion layers (a TIM) 780, which provide low thermal resistance interfaces. The heat spreader plates 78 may be made of high-thermal-conductivity materials such as copper, aluminum, or graphite composites. In some embodiments, the heat spreader plates 78 may also include integrated features such as vapor chambers, micro-channels, or embedded heat pipes to enhance heat dissipation. The heat spreader plates 78 may further interface with external cooling solutions, such as cold plates, heat sinks, liquid immersion cooling systems, thermos-electric coolers or the like to maximize heat removal from the package.

In some embodiments, the stack structure 70 may further include an encapsulant 700 to encapsulant flip chip joints. The encapsulant 700 may be disposed to fill the spaces between adjacent components within the stack structure 70, such as between the memory components 73, the bridge components 75, the HTC interposer 77, and surrounding elements. The encapsulant 700 may provide mechanical support, environmental protection, and additional thermal conduction paths (when a HTC encapsulant is used), depending on the selected material. In certain embodiments, the encapsulant 700 may comprise a non-conductive paste or film, an epoxy-based molding compound, a thermally conductive polymer to assist in dissipating heat from densely packed components within the stack structure 70.

As shown in FIG. 5A, a thermal element 72 may be attached to lateral surfaces of the stack structure 70, and may thereby be thermally coupled to the lateral surfaces of the stack structure 70 for direct lateral heat dissipation. In this configuration, the thermal element 72 may be thermally coupled to a lateral surface of HTC interposer 77. In some embodiments, the thermal element 72 may additionally extend onto or be disposed on the upper surface of the interposer 71, and thereby be thermally coupled to the interposer 71 as well.

In certain embodiments, the thermal element 72 may comprise a HTC material. The HTC material may be provided in the form of a solid bulk structure, a composite filler comprising thermally conductive particles dispersed in a polymeric matrix or a combination of TIM and heat spreader. In some implementations, the thermal element 72 may be formed by filling a cavity created between the lateral surfaces of the stacked dies and an outer encapsulant or mold wall with a HTC filler. The filler may then be cured or solidified to form a conformal thermal structure in direct or indirect contact with the stacked dies. Such filler-based thermal elements are particularly suitable for panel-level or wafer-level packaging processes and allow effective thermal contact with complex lateral geometries of multi-die stacks.

Suitable HTC materials may include, but are not limited to, aluminum nitride (AlN), which has a thermal conductivity of approximately 170 to 321 W/m·K; silicon carbide (SiC), with a thermal conductivity of approximately 120 to 270 W/m·K; synthetic diamond, which can exhibit an extremely high thermal conductivity greater than 1500 W/m·K; and metallic materials such as copper (Cu), tungsten (W), molybdenum (Mo), or ruthenium (Ru), with thermal conductivities typically ranging from about 100 to 400 W/m·K. In filler-based embodiments, thermally conductive particles such as metal (e.g., silver), AlN, boron nitride (BN), or graphite may be dispersed within a polymer resin or epoxy to form a composite thermal material that can conform to the shape of the die stack and make direct thermal contact with the lateral surfaces of individual dies.

Moreover, as shown in FIG. 5B, which is a schematic cross-sectional view along line C-C′ in FIG. 5A, the thermal element 72 may at least partially or fully surround the stack structure 70. In some embodiments, the thermal element 72 may be disposed in direct contact with or in close proximity to the lateral surfaces of the HTC interposer 77, and may further extend to cover the lateral sides of certain other components within the stack structure 70. Accordingly, the thermal element 72 may be thermally coupled to all or a majority of the lateral surfaces of the stack structure 70, thereby facilitating multidirectional heat dissipation from the stacked components. This lateral thermal coupling allows the thermal element 72 to efficiently intercept and redirect heat away from high-power elements, such as the semiconductor device 79 and memory components 73, toward external cooling interfaces or dedicated heat sinks, thereby improving the overall thermal performance and reliability of the semiconductor device package 7.

Referring to FIG. 5A, a heat spreader 74 may be disposed over the stack structure 70. The heat spreader 74 may be thermally coupled to the thermal element 72 to facilitate the dissipation of heat conducted from the lateral surfaces of the stack structure 70. This configuration allows heat collected by the thermal element 72, especially from higher-power regions such as the semiconductor device 79 or the memory components 73, to be transferred upward and laterally through the heat spreader 74, thereby enhancing the overall thermal management of the device.

In some embodiments, the heat spreader 74 may be attached to an upper surface of the semiconductor device 79, upper surfaces of the heat spreader plates 78, and upper portions of the thermal element 72 via a thermal interface material (TIM) 740. The TIM 740 may comprise a thermally conductive paste, film, or phase change material that minimizes thermal resistance at the interface, enabling efficient heat transfer from the stack structure 70 to the heat spreader 74. The heat spreader 74 may further be thermally connected to an external heat sink or integrated into a system-level cooling solution covering a cold plate, a liquid-cooled apparatus, a thermos-electric cooler or a combination thereof to dissipate the aggregated heat into the ambient environment.

Referring now to an exemplary thermal conduction mechanism within the semiconductor device package 7, the thermal flow paths for dissipating heat generated by active components are described in detail as follows.

The memory components 73 may generate heat denoted as h2, while the semiconductor device 79 (such as a high-performance GPU) may generate heat denoted as h3 during operation. Heat h2 may be conducted upward into the high-thermal-conductivity (HTC) interposer 77 from the memory components 73, whereas heat h3 may be conducted downward into the HTC interposer 77 from the semiconductor device 79 and also upward to the heat spreader 74. The HTC interposer 77, which is composed of a high thermal conductivity material (e.g., aluminum nitride or synthetic diamond), facilitates lateral thermal conduction along a first heat conduction path p1 toward the thermal element 72 attached to the sidewalls of the stack structure 70.

Subsequently, a portion of the combined heat h2 and h3 may be laterally transferred from the lateral surface of the HTC interposer 77 into the thermal element 72 and then into the heat spreader 74 along a second conduction path p2. The thermal element 72, which may be composed of a graphite composite, metal-carbon hybrid, or other thermally conductive material, provides a low-resistance thermal pathway for channeling the extracted heat into the heat spreader 74, thereby enhancing lateral and vertical heat dissipation from the stack structure 70.

Alternatively, a portion of the heat h2 and h3 may be conducted downward along a third thermal conduction path p3. In this path, the heat is transferred through the bridge components 75 to the underlying interposer 71, which may also include thermally conductive vias. From the interposer 71, the heat is then conducted laterally to the thermal element 72, and subsequently redirected upward to the heat spreader 74 for dissipation.

Additionally, a portion of heat h2 and h3 may propagate upward along a fourth conduction path p4, where it is transferred directly into the heat spreader plates 78. These plates function as intermediate thermal diffusion layers and conduct the heat upward to the overlying heat spreader 74, which may then release the accumulated thermal energy into an external cooling system, such as a cold plate or liquid-cooled assembly.

Further, a portion of heat h3 may be conducted upward along a fifth thermal conduction path p5. In this path, the heat is transferred through the TIM 740 to the heat spreader 74.

The integration of the thermal element 72 along the periphery of the stack structure 70 provides a critical enhancement in thermal performance. By establishing multiple lateral and vertical thermal escape routes, the thermal element 72 serves not only as a passive heat sink interface but also as an active heat-redirecting medium. This configuration improves the thermal dissipation efficiency of the entire package by mitigating thermal buildup at the core of the stack, reducing thermal resistance at critical junctions, and balancing heat flow across multiple planes. Consequently, the presence and placement of the thermal element 72 contribute significantly to thermal uniformity and operational stability of high-power semiconductor devices within densely integrated packages.

Thermal metamaterials refer to engineered material structures that enable heat transfer control beyond what is achievable by conventional materials. These may include composite or layered arrangements of materials like SiO2, graphene, silicon, carbon nanotubes, or boron arsenide (BAs), arranged to direct heat laterally or vertically as desired. The integration of such structures into semiconductor device packages allows for targeted heat dissipation routes, protection of thermally sensitive components, and reduced thermal crosstalk in dense chiplet configurations, particularly within 2.5D and 3D heterogeneous integration platforms.

The design of ring-shaped or trench-based thermal-guiding structures using CMOS-compatible materials such as SiO₂ and graphene can facilitate efficient lateral heat spreading away from thermally sensitive components such as GPU cores or HBM stacks.

By embedding such metamaterial structures around or adjacent to the lateral surfaces of the HTC interposer or memory stack, it is possible to reduce thermal crosstalk between heterogeneous dies (e.g., between ASIC and HBM in 2.5D packages) and direct heat efficiently to external heat spreaders. These structures may be fabricated using standard FEOL-compatible processes including patterning, trench etching, ALD/CVD deposition, and CMP.

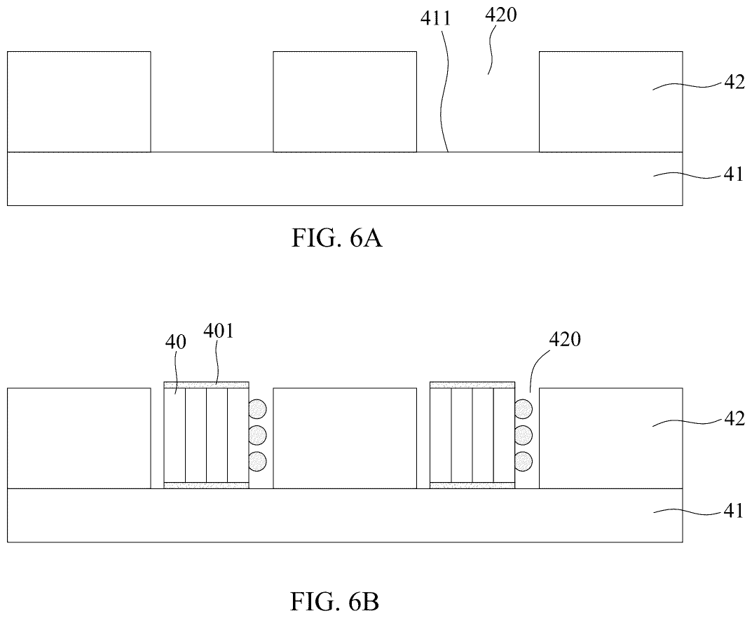

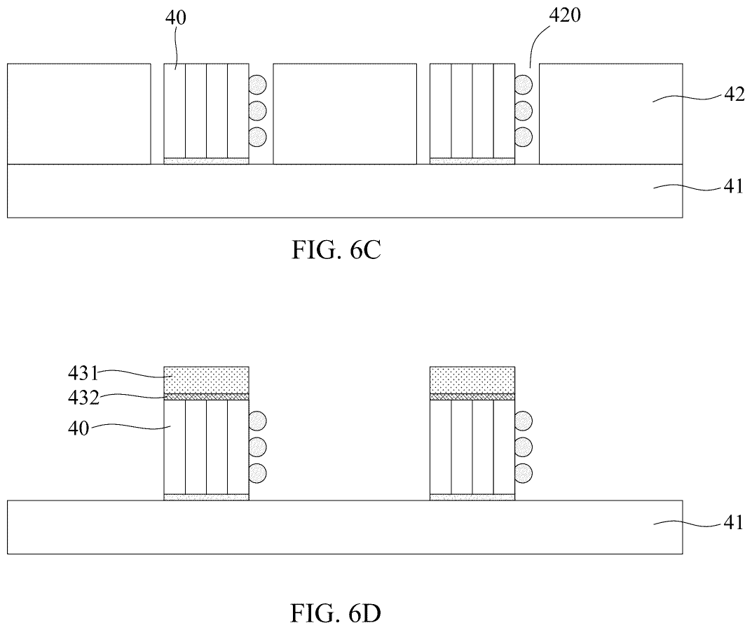

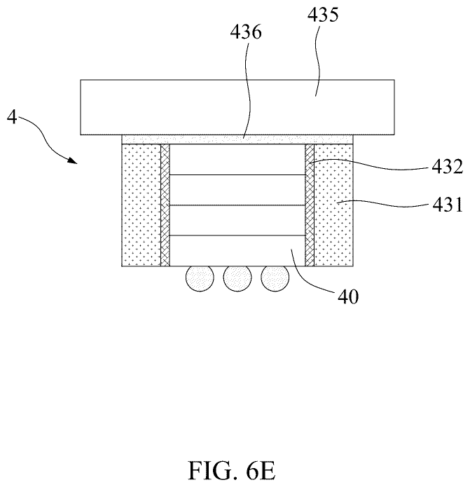

FIG. 6A, FIG. 6B, FIG. 6C, FIG. 6D and FIG. 6E illustrate one or more stages of an example of a method for manufacturing a semiconductor device package in accordance with some embodiments of the present disclosure.

Referring first to FIG. 6A, a carrier 41 and a mask 42 are provided. The carrier 41 includes a release layer 411 formed on its upper surface. The mask 42 is then disposed on the release layer 411. The mask 42 may be formed from a rigid or semi-rigid material and includes a plurality of cavities 420 configured to accommodate individual stack structures.

As shown in FIG. 6B, a plurality of stack structures 40 are prepared. Each stack structure 40 may be similar to the stack structure 10 illustrated in FIG. 1A. However, unlike the structure shown in FIG. 1A, the lateral surfaces of the stack structures 40 may be encapsulated in a molding compound 401

Each stack structure 40 is inserted into a respective cavity 420 in the mask 42, and the bottom of each stack rests on the release layer 411. In this configuration, one lateral surface of each stack structure 40 (i.e., the side facing away from the carrier 41) remains exposed and accessible for processing.

Referring to FIG. 6C, the molding compound 401 present on the exposed lateral surface of each stack structure 40 is removed. This removal step may be performed using a selective plasma etching, mechanical grinding process, wet etching or a combination thereof.

In FIG. 6D, after the exposed molding compound has been removed, a thermal element 431 is then attached to the cleaned lateral surface of the stack structure 40 and followed by the mask 42 removed. In some embodiments, the thermal element 431 is bonded to the lateral surface via a thermal interface material (TIM) 432, which ensures low thermal resistance and secured mechanical attachment. The thermal element 431 may be composed of a HTC material such as graphite composite, carbon-based metal matrix, aluminum-based structure, or the like.

After this step, the stack structure 40 may be rotated or reoriented such that another one of its lateral surfaces, still covered by the molding compound 400, is now facing upward. The process steps described in FIGS. 6B, 6C, and 6D are then repeated on this new lateral surface: the molding compound is removed, and a thermal element 431 is attached via a TIM layer 432. This rotation and attachment process may be repeated until thermal elements 431 are affixed to all four lateral sides of the stack structure 40.

Referring to FIG. 6E, upon completion of the above steps, the resulting assembly constitutes the semiconductor device package 4. In this configuration, thermal elements 431 are disposed along each of the lateral surfaces of the stack structure 40, providing effective heat extraction from the sidewalls of the stack structure.

Additionally, a top-mounted thermal element 435 may be disposed atop the stack structure 40. In some embodiments, the thermal element 435 is thermally and mechanically attached to the upper surface of the stack structure 40 via a TIM layer 436. The TIM layer 436 facilitates efficient heat transfer between the top surface of the stack structure 40 and the thermal element 435.

Together, the side-mounted thermal elements 431 and the top-mounted thermal element 435 form a comprehensive thermal dissipation scheme, allowing heat generated within the stack structure 40 to be conducted away through multiple surfaces. This configuration enhances the overall cooling efficiency of the package and supports stable operation under high thermal loads. The stack structure 40 can be replaced by the stack structure 10 in FIG. 1A, the stack structure 20 in FIG. 2A, or the stack structure 70 in FIG. 5A

In some embodiments, the semiconductor device package 4 may be identical or similar in structure and function to the semiconductor device package 1 illustrated in FIGS. 1A and 1B.

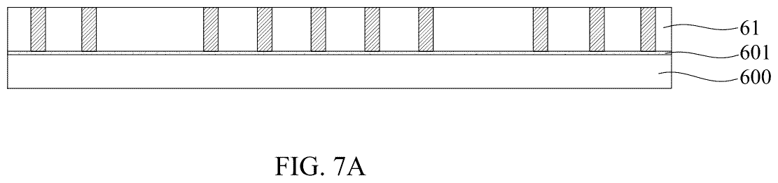

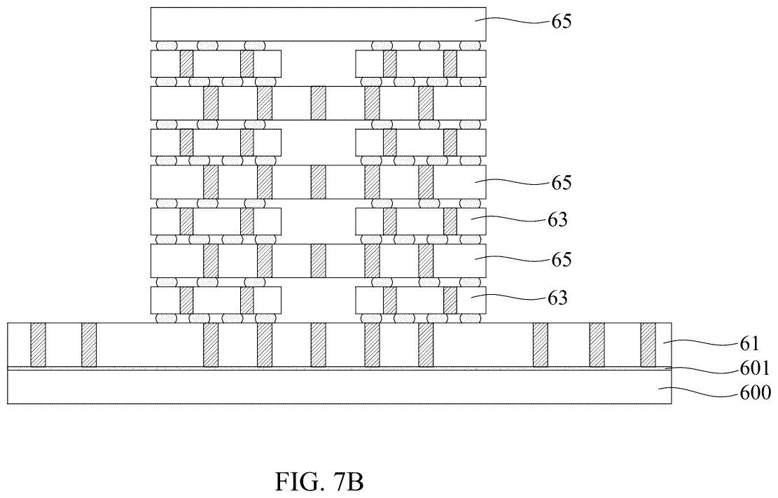

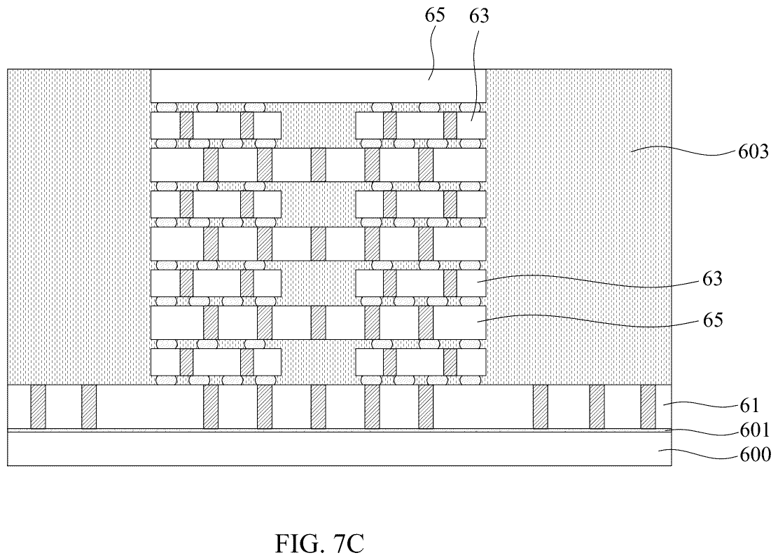

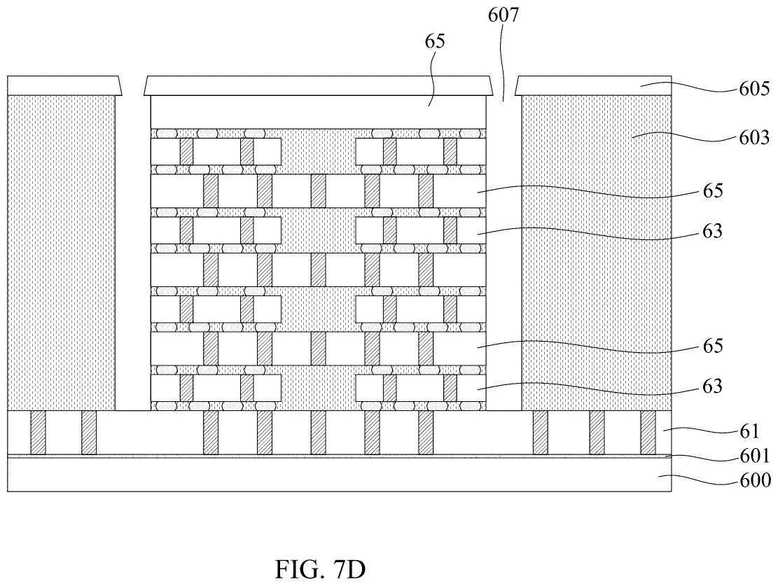

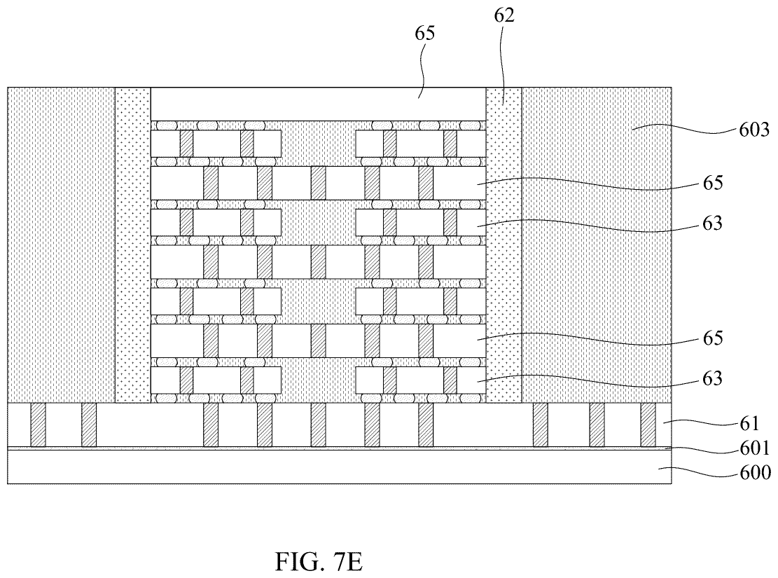

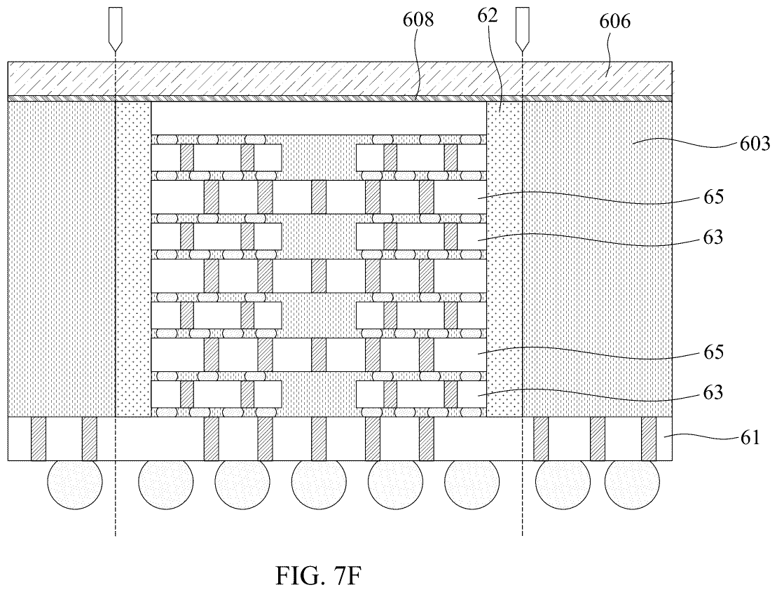

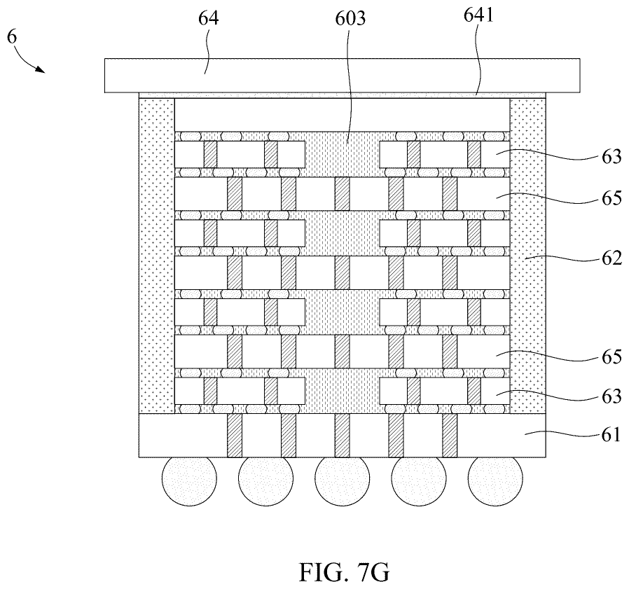

FIG. 7A, FIG. 7B, FIG. 7C, FIG. 7D, FIG. 7E, FIG. 7F and FIG. 7G illustrate one or more stages of an example of a method for manufacturing a semiconductor device package in accordance with some embodiments of the present disclosure.

Referring to FIG. 7A, a carrier 600 is provided. A release layer 601 is formed on an upper surface of the carrier 600, and a logic component 61 is disposed over the release layer 601.

Referring to FIG. 7B, a plurality of peripheral circuitry dies 63 and a plurality of memory array dies 65 are sequentially stacked on the logic component 61. In some embodiments, the peripheral circuitry dies 63 are first mounted on the logic component 61, followed by the stacking of the memory array dies 65 on the peripheral circuitry dies 63. Each die may be electrically and thermally coupled to its adjacent die through inter-die connections such as micro-bumps or hybrid bonds. Die stacking can be achieved by either flip chip assembly based on solder bumps, micro-bumps, or hybrid bonds. Flip chip assembly can be achieved with the use of an encapsulant such as an underfill or a non-conductive paste or film.

Referring to FIG. 7C, an encapsulant 603 is deposited over the logic component 61, and used to encapsulate the peripheral circuitry dies 63 and the memory array dies 65. The encapsulant 603 may comprise an epoxy molding compound (EMC), a photo-imageable thick-film photoresist, or other dielectric materials to provide structural support and environmental protection.

Referring to FIG. 7D, a mask 605 is applied above the topmost memory array die 65 and the encapsulant 603. A portion of the encapsulant 603 is removed via a masking and etching process to form a cavity 607. Through this cavity 607, at least a portion of the upper surface of the logic component 61, the lateral surfaces of the peripheral circuitry dies 63, and the lateral surfaces of the memory array dies 65 are exposed.

Referring to FIG. 7E, a HTC filler material is filled into the cavity 607 to form a thermal element 62. The HTC filler may include materials such as aluminum nitride (AlN), diamond particles, or graphite composites, which exhibit thermal conductivities significantly higher than those of conventional molding compounds.

Referring to FIG. 7F, a new carrier 606 is then provided and is temporarily bonded to the topmost memory array die 65 and the surrounding encapsulant 603 using a release layer 608. This is then followed by the removal of the carrier 600 and the release layer 601 and then subsequently by a bumping process to form bumps for external connection and the removal of the second carrier 606. A dicing process then ensues to singulate the resultant stack structure in FIG. 7F.

Referring to FIG. 7G, a heat spreader 64 is attached to the topmost memory array die 65 to complete the semiconductor device package 6 following bonding of the stack structure in FIG. 7F to the next-level component. In some embodiments, the heat spreader 64 is thermally coupled to the memory array die 65 via a TIM layer 641. The heat spreader 64 may comprise a metal plate or a composite material with high thermal conductivity which may optionally include embedded vapor chambers, heat pipes, and/or microfluidic cooling structures to further enhance thermal dissipation. The process of FIG. 7A to FIG. 7F can also be applied on the stack structure 10 in FIG. 1A.

The resulting semiconductor device package 6 may be structurally and functionally identical or similar to the semiconductor device package 2 as illustrated in FIG. 2A and FIG. 2B, particularly in terms of its stack configuration and thermal management architecture.

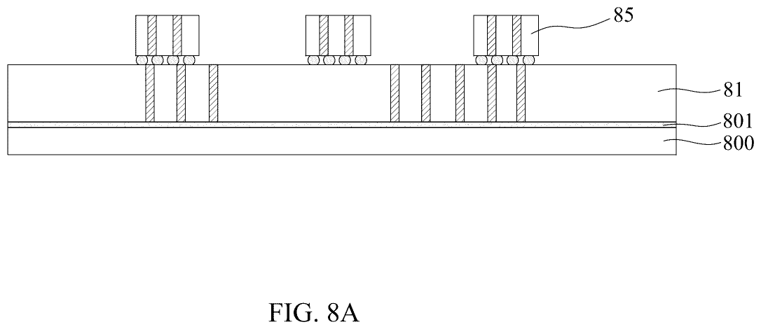

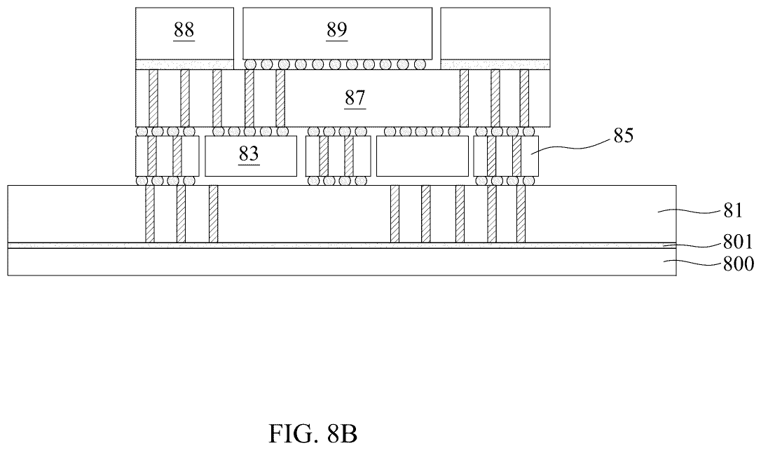

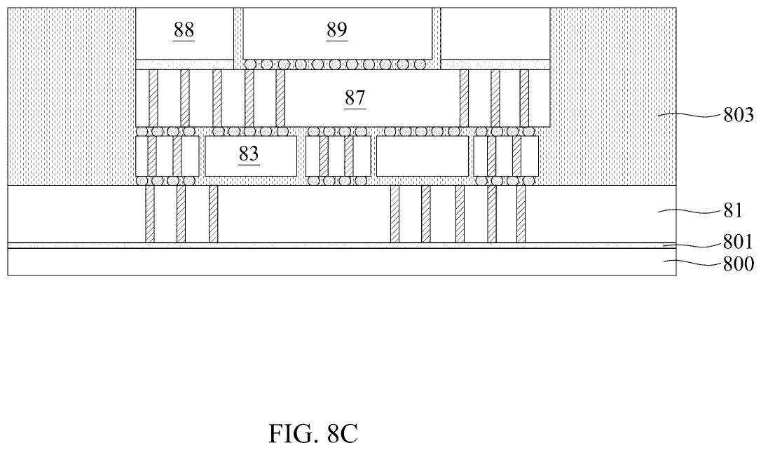

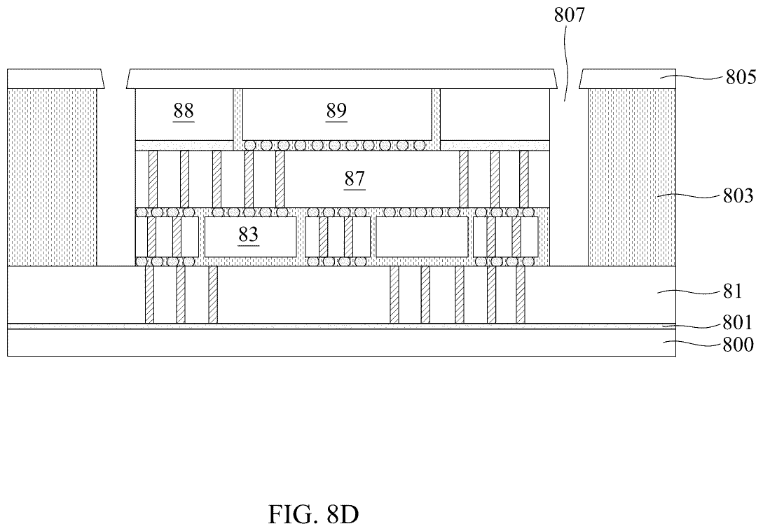

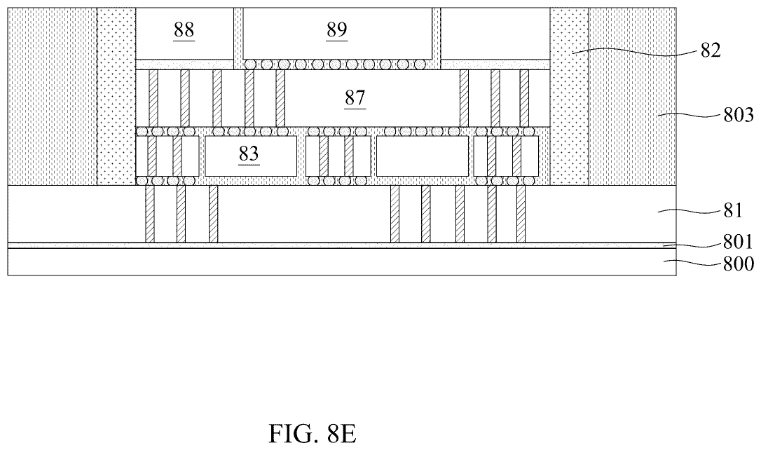

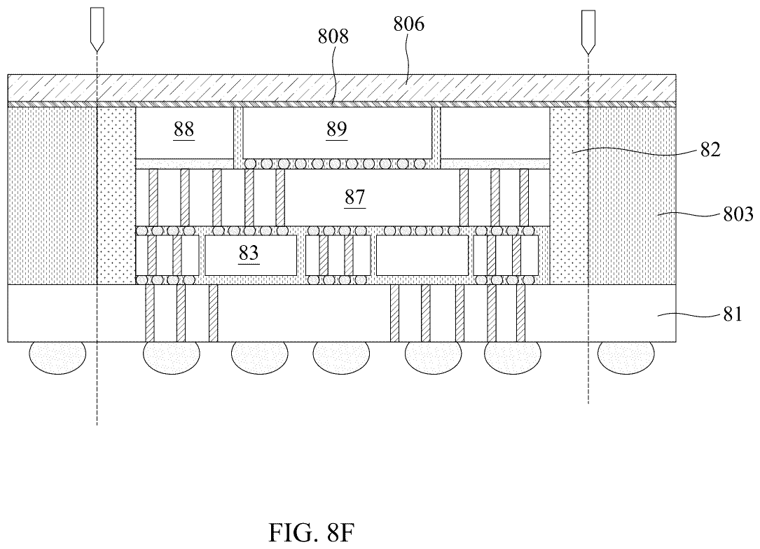

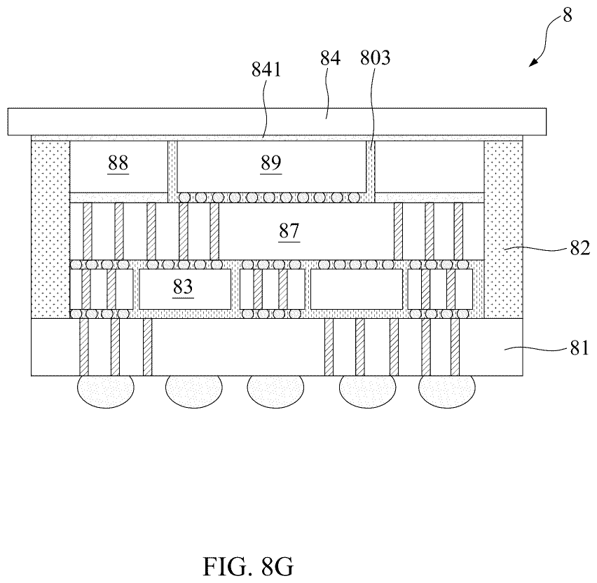

FIG. 8A, FIG. 8B, FIG. 8C, FIG. 8D, FIG. 8E, FIG. 8F and FIG. 8G illustrate one or more stages of an example of a method for manufacturing a semiconductor device package in accordance with some embodiments of the present disclosure.

Referring to FIG. 8A, a carrier 800 is provided. A release layer 801 is formed on an upper surface of the carrier 800. An interposer 81 is disposed on the release layer 801. The interposer 81 may be a silicon-based (or a glass-based) interposer that includes a plurality of through-silicon vias (TSVs) for signaling and power routing. A plurality of bridge components 85 are mounted to the upper surface of the interposer 81 via micro-bump connections. The bridge components 85 may be one of the bridge candidates mentioned for FIG. 5A which is not reiterated herein for brevity.

Referring to FIG. 8B, a HTC interposer 87, pre-bonded with memory components 83, is then bonded to the bridge components 85, followed by bonding of the heat spreader plates 88, and a semiconductor device 89 on the HTC interposer 87. The HTC interposer 87 can be made of a material with thermal conductivity greater than 148 W/m·K, such as aluminum nitride or synthetic diamond. The memory components 83 may include memory dies or high-bandwidth memory (HBM) stacks. One or more heat spreader plates 88 are attached to the HTC interposer 87 via adhesive layers. The semiconductor device 89 (e.g., a GPU) is bonded to the upper surface of the HTC interposer 87. Bonding is achieved by flip chip assembly based on solder bumps, micro-bumps or copper hybrid bonding.

Referring to FIG. 8C, an encapsulant 803 is applied to encapsulate the exposed components, including the interposer 81, bridge components 85 (show this on FIG. 8B), memory components 83, HTC interposer 87, heat spreader plates 88, and semiconductor device 89. The encapsulant 803 may comprise an epoxy molding compound or similar dielectric material for mechanical and environmental protection.

Referring to FIG. 8D, a mask 805 is applied over the encapsulant 803, the heat spreader plates 88, and the semiconductor device 89. A portion of the encapsulant 803 is selectively removed using masking and etching to form a cavity 807. The cavity 807 exposes at least part of the upper surface of the interposer 81 and at least one lateral surface of the HTC interposer 87.

Referring to FIG. 8E, a high-thermal-conductivity (HTC) filler is dispensed into the cavity 807 to form a thermal element 82. The HTC filler may comprise thermally conductive materials containing metal particles and/or diamond particles, or in the form of carbon-based composites.

Referring to FIG. 8F, a second carrier 806 is then bonded to the heat spreader plates 88, the semiconductor device 89, and the encapsulant 803 using a release layer 808. Then, the carrier 800 and the release layer 801 are removed, followed by bumping process to form bumps for external connection. Following the removal of the second carrier 806, a dicing process is performed to singulate the resultant stack structure.

Referring to FIG. 8G, a heat spreader 84 is mounted on top of the heat spreader plates 88, the thermal element 82 and the semiconductor device 89 following bonding of the stacked structure to the next-level component. In some embodiments, the heat spreader 84 is bonded using a thermal interface material (TIM) layer 841 to ensure optimal thermal contact with the top surfaces of the heat spreader plates 88, the thermal element 82 and the semiconductor device 89. The heat spreader 84 may further be thermally coupled with external cooling modules, such as a cold plate, a vapor chamber, a liquid immersion apparatus, a thermos-electric cooler, the like or a combination thereof.

The resulting semiconductor device package 8 may be structurally and functionally identical or similar to the semiconductor device package 7 illustrated in FIGS. 5A and 5B.

In summary, the present disclosure provides a semiconductor device package incorporating one or more lateral thermal elements disposed on the lateral surfaces of a stacked structure. These lateral thermal elements, formed of high-thermal-conductivity materials, are thermally coupled to heat-generating components such as memory dies, logic dies, and high-performance processors via exposed lateral surfaces as well as a network of thermal escape routes comprising thermal STIs, thermal material structures, thermal vias, thermal bumps and thermal planes. By establishing additional thermal pathways orthogonal to the conventional one-sided chip backside conduction route, the lateral thermal elements enable multidirectional heat dissipation. Moreover, when thermally connected to a top heat medium, the lateral thermal elements can efficiently transfer accumulated heat from the stack structure to external cooling structures. This configuration enhances the overall thermal management of the package, reduces thermal resistance, and enables reliable operation of high-power semiconductor components under increasing thermal loads—thereby supporting higher integration density and improved performance in advanced packaging applications.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein are described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations on the present disclosure.

What is claimed is:

1. A semiconductor device package, comprising:
a stack structure comprising a plurality of electronic components vertically stacked relative to each other, each of the plurality of electronic components being configured to provide electrical connectivity in a vertical direction; and
a first thermal element surrounding lateral surfaces of the stack structure and thermally coupled to a lateral surface of at least one of the plurality of electronic components.

2. The semiconductor device package of claim 1, wherein the first thermal element comprises a high-thermal-conductivity material which is thermally coupled to the lateral surface of at least one of the plurality of electronic components.

3. The semiconductor device package of claim 1,
wherein the stack structure comprises a plurality of memory devices that are electrically connected to each other and vertically stacked relative to one another, and wherein the memory devices are thermally coupled to the first thermal element.

4. The semiconductor device package of claim 1, wherein the stack structure comprises:
a memory array die;
a peripheral circuitry die stacked beneath the memory array die; and
a logic die stacked beneath the peripheral circuit die;
wherein the memory array die, the peripheral circuitry die and the logic die are thermally coupled to the first thermal element.

5. The semiconductor device package of claim 4, further comprising a first high-thermal-conductivity (HTC) interposer having a thermal conductivity greater than a thermal conductivity of silicon, wherein the first HTC interposer is stacked between the memory array die and the peripheral circuitry die, and wherein a lateral surface of the first HTC interposer, a lateral surface of the memory array die and a lateral surface of the peripheral circuitry die are thermally coupled to the first thermal element.

6. The semiconductor device package of claim 5, wherein the memory array die comprises a front-end-of-line (FEOL) layer and a back-end-of-line (BEOL) layer,
wherein the FEOL layer includes a thermal shallow trench isolation (STI) structure thermally coupled to a first thermal via extending through the memory die,
wherein the BEOL layer includes a thermal bump thermally coupled to the STI structure and to the first HTC interposer through a second thermal via and wherein the STI structure, the first and second thermal vias, and the thermal bump are thermally coupled to the first thermal element.

7. The semiconductor device package of claim 4, further comprising a redistribution layer disposed over the first HTC interposer and thermally coupled to the memory array die through a thermal bump, wherein the redistribution layer comprises a heat dissipation structure thermally coupled to the thermal bump and the first thermal element.

8. The semiconductor device package of claim 7, wherein the heat dissipation structure comprises a third thermal via and a thermal plane.

9. The semiconductor device package of claim 1, wherein the stack structure comprises:
an interposer;
a memory component disposed over the interposer;
a bridge component disposed over the interposer;
a second high-thermal-conductivity (HTC) interposer having a thermal conductivity greater than a thermal conductivity of silicon, wherein the second HTC interposer is disposed over the memory component and the bridge component;
a semiconductor device disposed over the second HTC interposer; and
a heat spreader plate disposed over the second HTC interposer;
wherein the interposer, the bridge component, the second HTC interposer and the heat spreader plate are thermally coupled to the first thermal element.

10. A semiconductor device package comprising:
a plurality of electronic components stacked in a first direction; and
a first thermal element surrounding the plurality of electronic components;
wherein the first thermal element is configured to conduct heat generated by at least the plurality of electronic components in a second direction toward the first thermal element and in a first direction toward the second thermal element,
wherein the first direction and the second direction are substantially orthogonal to each other.

11. The semiconductor device package of claim 10, wherein the plurality of electronic components comprises:
a logic die;
a peripheral circuitry die disposed over the logic die; and
a memory array die disposed over the peripheral circuitry die;
wherein heat generated by the electronic components is transferred to the first thermal element which, in turn, is thermally coupled to the second thermal element in the first direction.

12. The semiconductor device package of claim 11, further comprising a first high-thermal-conductivity (HTC) interposer, wherein the first HTC interposer is configured to conduct heat generated by the memory array die to the first thermal element in the second direction.

13. The semiconductor device package of claim 12, wherein the memory array die comprises a first thermal via configured to transfer heat from another die above the memory die, and wherein a front-end-of-line (FEOL) layer of the memory array die comprises a thermal shallow trench isolation (STI) structure thermally connected to the first thermal via, and wherein a back-end-of-line (BEOL) layer of the memory array die comprises a second thermal via thermally coupled to the front-end-of-line (FEOL) layer, and wherein a thermal bump is thermally coupled to the memory array die.

14. The semiconductor device package of claim 13, wherein the heat generated by the memory array die is transferred to the first HTC interposer in the first direction through a heat dissipation structure of a redistribution layer over the first HTC interposer and/or transferred to the first thermal element in the second direction through the heat dissipation structure of the redistribution layer.

15. The semiconductor device package of claim 14, wherein the heat generated by the memory array die is transferred to the first HTC interposer in the first direction through a third thermal via of the dissipation structure of the redistribution layer on the HTC interposer and/or transferred to the first thermal element in the second direction through a dissipation structure of a thermal plane of the redistribution layer.

16. The semiconductor device package of claim 10, wherein the plurality of electronic
components comprises:
an interposer;
a memory component disposed over the interposer;
a bridge component disposed over the interposer;
a second high-thermal-conductivity (HTC) interposer, wherein the second HTC interposer is disposed over the memory component and the bridge component;
a semiconductor device disposed over the second HTC interposer; and
a heat spreader plate disposed over the second HTC interposer;
wherein heat generated by the memory component and the semiconductor device is transferred to the first thermal element in the second direction through the second high-thermal-conductivity (HTC) interposer, the heat spreader plate and/or the interposer.

17. The semiconductor device package of claim 10, further comprising a second thermal element disposed over the plurality of electronic components and configured to absorb heat from the first thermal element in the first direction.

18. A method of manufacturing a semiconductor device package, comprising:
providing a carrier;
arranging a stack structure comprising a plurality of electronic components stacked relative to one another on the carrier; and
disposing a first thermal element on a lateral surface of the stack structure.

19. The method of claim 18, further comprising: providing a mask with a through hole on an upper surface of the carrier;
wherein the stack structure is received in the through hole and disposed on the upper surface of the carrier, and
a lateral surface of the stack structure, on which the first thermal element is disposed, faces away from the upper surface of the carrier.

20. The method of claim 18, wherein the stack structure is arranged on an upper surface of the carrier such that a stacking direction of the plurality of electronic components is substantially perpendicular to the upper surface of the carrier, and further comprising:
providing an encapsulant to encapsulate the stack structure;
forming a cavity in the encapsulant to expose a lateral surface of the stack structure; and
providing a high-thermal-conductivity filler in the cavity to form the first thermal element.
